(19) United States
(12) Patent Application Publication
(10) Pub. No.: US 2008/0251833 A1
(43) Pub. Date: Oct. 16, 2008

(54) Integrated circuits and methods of manufacture

(76) Inventors: Michael Specht, Munich (DE); Franz Hofmann, Munich (DE); Nicolas Nagel, Dresden (DE)

Correspondence Address: SLATER & MATSIL, L.L.P., 17950 PRESTON ROAD, SUITE 1000, DALLAS, TX, 75252, US

(21) Appl. No.: 11/786,751

(22) Filed: Apr. 12, 2007

(51) Int. Cl. H01L 29/788; H01L 21/336

(52) U.S. Cl. 257/316; 438/257; 257/E29.3; 257/E21.422

(57) ABSTRACT

In various embodiments of the invention, integrated circuits and methods of manufacturing integrated circuits are provided. In an embodiment of the invention, an integrated circuit having at least one memory cell is provided. The memory cell includes a dielectric layer disposed above a charge storage region, a word line disposed above the dielectric layer, and a control line disposed at least partially above at least one sidewall of the dielectric layer.

### TECHNICAL FIELD

Embodiments of the invention relate to integrated circuits having a memory cell and methods to manufacturing an integrated circuit having a memory cell.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates an integrated circuit having a memory cell in accordance with an embodiment of the present invention;

FIG. 2A illustrates an integrated circuit having a floating gate memory cell in accordance with one embodiment of the present invention;

FIGS. 2B and 2C illustrate a reduction in the effective thickness of the tunnel dielectric as a function of a differential voltage applied between the word line and control line of the memory cell in accordance with one embodiment of the present invention;

FIG. 3A illustrates a top view of an integrated circuit having a NAND memory array portion employing memory cells in accordance with one embodiment of the present invention;

FIG. 3B illustrates a top view of an integrated circuit having a virtual ground memory array portion employing memory cells in accordance with one embodiment of the present invention;

FIG. 4A illustrates an exemplary method for manufacturing an integrated circuit having a memory cell in accordance with the present invention;

FIG. 4B illustrates a method for manufacturing an integrated circuit having an arrangement of memory cells in accordance with an embodiment of the present invention;

FIG. 5A illustrates specific processes for manufacturing an integrated circuit having a memory cell arrangement in a NAND configuration in accordance with an embodiment of the present invention;

FIGS. 5B to 5J illustrate perspective views of an integrated circuit having a memory cell arrangement in a NAND configuration at various stages of processing in accordance with an embodiment of the present invention;

FIG. 6A illustrates specific processes for manufacturing an integrated circuit having a memory cell arrangement in a virtual ground configuration in accordance with an embodiment of the present invention;

FIGS. 6B to 6I illustrate perspective views of an integrated circuit having a memory cell arrangement in a virtual ground configuration at various stages of processing in accordance with an embodiment of the present invention; and

FIGS. 7A and 7B show a memory module (FIG. 7A) and a stackable memory module (FIG. 7B) in accordance with an embodiment of the invention.

For clarity, previously described features retain their reference numerals in subsequent drawings.

### DETAILED DESCRIPTION OF ILLUSTRATIVE EMBODIMENTS

As used herein the terms connected and coupled are intended to include both direct and indirect connection and coupling, respectively.

Embodiments of the invention relate to an integrated circuit having memory cells, to an integrated circuit having memory cell arrangements, and methods of manufacturing same.

Non-volatile memory arrays are widely used in many electronic devices, be they in dedicated, peripheral, or embedded form, and their implementation continues to expand into new applications. Memory technologies, such as Flash, ferro-electric and magnetic random access memory, and phase change memory show particular promise, as the retention of data in these types of memories without the need for power provides significant positive effects, especially in mobile applications.

An impediment slowing the wider adoption of non-volatile memory devices is the high programming voltage typically needed for non-volatile memory cells. Flash (EEPROM) non-volatile memory cells, for example, typically require programming voltages in the range of 15 to 20V. Charge pump circuitry can be used to boost a lower supply voltage to the range needed, although with a relatively high rate of power dissipation, thereby draining a portable power source, such as a battery, very quickly.

One characteristic of non-volatile memories is the relatively slow speed with which programming operations are performed, usually in the range of microseconds. Faster programming speeds in conventional memory cells would require either the use of higher programming voltages, or the use of thinner dielectric layers in the gate stack of the memory cell. Use of thinner gate stack dielectric layers is problematic, as the cell's lifetime is dramatically reduced by further decreasing the gate stack dielectric layers beyond the present state of the art.

In the context of this description, a “volatile memory cell,” may be understood as a memory cell storing data, the data being refreshed during a power supply voltage of the memory system being active, in other words, in a state of the memory system, in which it is provided with power supply voltage. In contrast thereto, a “non-volatile memory cell” may be understood as a memory cell storing data, wherein the stored data are kept even when the power supply voltage of the memory system is not active. A “non-volatile memory cell” in the context of this description includes a memory cell, the stored data of which may be refreshed after an interruption of the external power supply. As an example, the stored data may be refreshed during a boot process of the memory system after the memory system had been switched off or had been transferred to an energy deactivation mode for saving energy, in which mode at least some or most of the memory system components are deactivated. Furthermore, the stored data may be refreshed on a regular timely basis, but not, as with a “volatile memory cell” every few picoseconds or nanoseconds or milliseconds, but rather in a range of hours, days, weeks or months.

Memory Cell Architecture

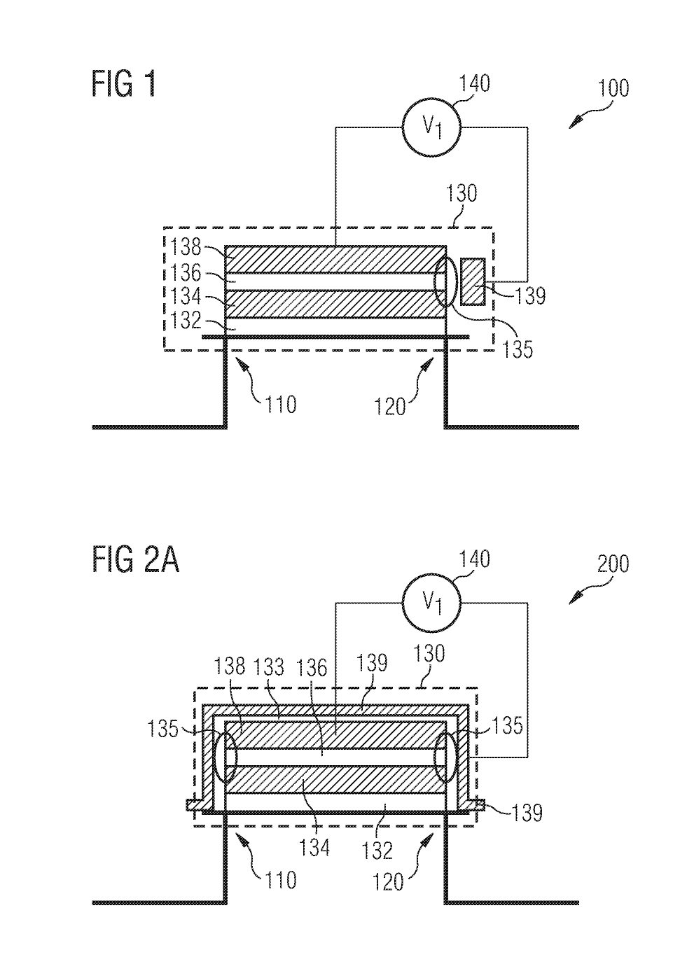

FIG. 1 illustrates an integrated circuit having a memory cell 100 in accordance with an embodiment of the present invention. In one embodiment of the invention, the memory cell 100 is a tunnel transistor memory cell 100.

The memory cell 100 includes a first source/drain region 110 and a second source/drain region 120, respectively, in or above a substrate, each of which may form either the drain terminal or the source terminal of the memory cell 100. In a particular embodiment of the invention, adjacent memory cells 100 are arranged in a serially-coupled source-to-drain NAND string configuration. However, in an alternative embodiment of the invention, the memory cell string configuration may implement any other suitable configuration instead of the NAND string configuration. In an alternative embodiment, first source/drain regions 110 for adjacent transistors are coupled in parallel along a first bit line, and second source drain regions 120 are similarly coupled in parallel along a second bit line in a virtual ground memory cell configuration. These memory cell configurations are further illustrated below.

In one embodiment of the invention, the substrate is made of semiconductor material, although in another embodiment of the invention, other suitable materials can also be used, e.g., polymers. In an exemplary embodiment of the invention, the substrate is made of silicon (doped or undoped), in an alternative embodiment of the invention, the substrate is a silicon on insulator (SOI) substrate. As an alternative, any other suitable semiconductor material can be used for the substrate, for example semiconductor compound material such as gallium arsenide (GaAs), or indium phosphide (InP), but also any suitable ternary semiconductor compound material or quaternary semiconductor compound material such as indium gallium arsenide (InGaAs).

As those skilled in the art will appreciate, the memory cell 100 may be formed in a variety of different technologies, e.g., Flash memory, ferro-electric random access memory, magnetic random access memory, phase change memory, and the like.

The memory cell 100 further includes a gate stack region 130 arranged laterally between the first drain/source region 110 and the second drain/source region 120. An active region is arranged between the first drain/source region 110 and the second drain/source region 120. A conductive channel may be formed in the active region between the first drain/source region 110 and the second drain/source region 120 in response to the application of suitably selected voltages at the first drain/source region 110, the second drain/source region 120, the word line and the control line, which will be described in more detail below. The gate stack region 130 includes a first dielectric layer 132 disposed on or above the substrate between the first source/drain region 110 and the second source/drain region 120. The first dielectric layer 132 is, for example, a thermally grown oxide layer in the range of 5 nm to 15 nm. In a particular embodiment of the invention, the active region is composed of p-type semiconductor material such as e.g. silicon, and the first source/drain region 110 and the second source/drain region 120 are implanted as n-type regions. In an alternative embodiment, an n-well is used to construct the memory cell 100, in which case the active region will be made up of the n-type semiconductor material and the first source/drain region and the second source/drain region 120 will be implanted to form p-type regions, also referred to as p-type junctions. Furthermore, the active region may be of any particular length and/or periphery. A gate length may be, for example, in the range of 10 nm to 50 nm, although transistors of other dimensions may be used as those skilled in the art will appreciate.

The gate stack region 130 further includes a charge storage region 134 disposed on or above the first dielectric layer 132. A particular embodiment of the memory cell 100 is a floating gate memory cell, and in such an embodiment, the charge storage region 134 comprises a floating gate region, made for example from a layer of poly-Si, or a metallic material like tantalum nitride (TaN), tungsten nitride (WN), tungsten (W), titanium nitride (TiN), etc. In another embodiment, the memory cell 100 comprises a charge trapping memory cell, whereby the charge storage region 134 comprises a charge trapping region, such as a nitride, such as, e.g., Si₃N₄. These embodiments are further described below.

The gate stack region 130 further includes a second dielectric layer 136, referred to as a tunnel layer herein, the tunnel layer 136 having a predefined physical thickness (as shown in the vertical dimensions in FIG. 1). For example, the tunnel layer 136 may have a thickness of at least 10 nm, for example, 12 nm to 120 nm or greater. In a specific embodiment, the tunnel layer 136 is formed from an interpoly dielectric, and more particularly, a material which is substantially “trapless,” such as, e.g., silicon oxide (SiO₂), trapless nitride, hafnium silicate, aluminum oxide (Al₂O₃), aluminates (e.g., AlHfOₓ), or double-layer or triple-layer stacks like SiO₂/Si₃N₄/SiO₂. A feature of an embodiment of the present invention is to provide a mechanism by which the physical thickness of the tunnel layer 136 is reduced to a smaller effective thickness which permits charge to flow more easily through the tunnel layer 136, thus allowing lower programming voltages to be used. Furthermore, a feature of an embodiment of the invention is to provide a mechanism by which the physical thickness of the tunnel layer 136 may be set at a suitable level while changing its effective dielectric thickness. This may permit charge to flow more or less easily through the tunnel layer 136, thus allowing lower or higher programming voltages to be used, as will be described in more detail below.

In an embodiment of the invention, the wherein the charge passes between the word line and the charge storage region is determined as a function of a voltage difference applied between the control line and the word line.

The gate stack region 130 additionally includes a word line layer 138 which is coupled to the memory layer 134 via the second dielectric layer 136. In an exemplary embodiment, the word line layer is formed from doped poly-Si, Ti, TaN, WN, W, Cu, or other conductive material available in the particular process employed to form the memory cell 100.

Additionally included within the gate stack region 130 is a portion of a control line layer, the included portion of the control line 139 coupled to the word line 138 (being a portion of the word line layer) via the second dielectric layer 136 within area 135. In a particular embodiment, the control line layer is formed so as to be capacitively-coupled to the word line layer 138, i.e., through an indirect, non-conductive layer. The control line 139 may be formed from any of the aforementioned conductive materials available in the fabrication process, such as poly-Si, TaN, W, WN, TiN, and the like.

The word line layer and the control line layer are operable to receive a voltage difference V₁ 140, the voltage difference V₁ 140 producing an effective tunnel thickness within the tunnel layer 136 which is determined as a function of the applied voltage difference V₁ 140. In a particular embodiment of the invention, the applied voltage difference is of a magnitude and polarity which produces an effective tunnel thickness which is less than the predefined physical thickness of the tunnel layer 136. In such an embodiment, the polarity of the voltage difference provides a forward charge path from the word line layer to the charge storage layer, the word line voltage being higher than the control line voltage in this embodiment. This allows charge to flow more easily through the tunnel layer 136, thus allowing lower programming voltages to be used. The magnitude of the voltage difference may range to 10V, particular embodiments being, 0.5V, 1V, 2V, 3V, 4V, 5V, 6V, 7V, 8V, for example.

In another embodiment of the invention, the applied voltage difference is of a magnitude and polarity which produces an effective tunnel thickness which is greater than the predefined physical thickness of the tunnel layer 136. In such an embodiment, the polarity of the voltage difference is defined to provide a reverse charge path from the word line 138 to the control line 139, the voltage on the word line 138 being lower than that applied to the control line 139. In this mode, the transfer of charge between the word line 138 and the charge storage region 136 is inhibited. Such an operation may be provided, for example, to further deactivate unselected memory cells. In another embodiment along these lines, the tunnel layer 136 is very thinly formed (e.g., below approximately 6 nm to approximately 10 nm) to provide sufficient charge transfer between the word line 138 and the charge storage region 136 under very low programming voltages (e.g., 6V to 10V). An inhibiting voltage difference can then be applied to unselected memory cells, deactivating all cells (or at least those cells in a possibly conducting state) except the selected cell. Accordingly, the magnitude and polarity of the applied differential voltage can be chosen to provide: (i) a passing voltage operable to reduce the effective tunnel thickness of the tunnel layer 136, (ii) an inhibiting voltage operable to increase the effective tunnel thickness of the tunnel layer 136, or a combination of (i) and (ii).

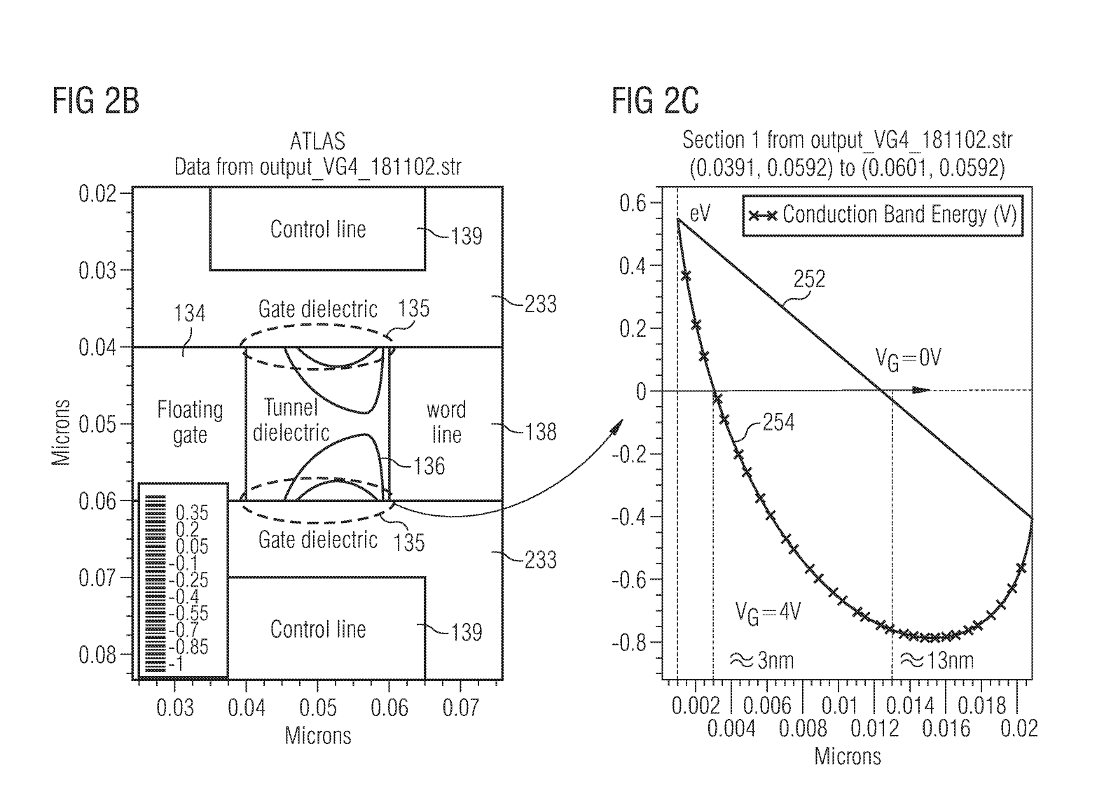

FIG. 2A illustrates an integrated circuit having the memory cell 200, wherein the memory cell 200 is a floating gate memory cell in accordance to one embodiment of the present invention. Previously identified features have retained their reference numerals for clarity. In this embodiment, the first dielectric layer 132 and the second dielectric layer 136, and the charge storage region 134 form a floating gate structure known in the art. In a particular example of this structure, the active region has a length of about 20 nm, the floating gate is constructed from Ti having a thickness of 15 nm, the tunnel dielectric 136 consists of 20 nm thick TiO₂, the word line 138 is formed from 15 nm thick Ti, and the control line 139 is constructed of TiN. The memory cell may be formed to have a particular feature size F, for example approximately 10 nm to approximately 60 nm.

In an alternative embodiment of the invention, the first dielectric layer 132 and the second dielectric layer 136, and the charge storage region 134 compose a charge trapping storage structure (single bit or multi-bit cells). In such an embodiment, the first dielectric layer 132 and the second dielectric layer 136 may be oxide layers (e.g., SiO₂ or Al₂O₃, etc.) having a thickness of about 5 nm to 15 nm, and the charge trapping layer 134 may be composed of N, e.g., Si₃N₄, having a thickness of about 5 nm to 15 nm.

The second dielectric layer 136 may include a dielectric layer stack including one or more dielectric layers being formed above one another, wherein charge carriers can be trapped in at least one dielectric layer. By way of example, the second dielectric layer 136 may include or consist of one or more materials being selected from a group of materials that consists of: aluminium oxide (Al₂O₃), yttrium oxide (Y₂O₃), hafnium oxide (HfO₂), lanthanum oxide (LaO₂), zirconium oxide (ZrO₂), amorphous silicon (a-Si), tantalum oxide (Ta₂O₅), titanium oxide (TiO₂), and/or an aluminate. An example for an aluminate is an alloy of the components aluminium, zirconium and oxygen (AlZrO).

The third dielectric layer 133, and control line 139 may be as described above, or be of different dimensions and/or material compositions, depending upon the particular process employed. In an embodiment of the invention, the material for the third dielectric layer has excellent isolation properties even under high applied voltage since the only functions of the third dielectric are to offer the field required to transform the second dielectric into a tunnel barrier and secondly to provide the dielectric isolation of the charge storage region. The material is therefore thought to exhibit a high band gap of more than 5 eV, a high conduction band offset and valence band offset. For instance this could be Al₂O₃, SiO₂, AlN, Hf Silicates with high SiO content.

As illustrated in FIG. 2A, the word line 138 extends along a first longitudinal axis (i.e., along the drawing's z-axis, in other words, the first longitudinal axis runs perpendicular to the paper plane of FIG. 2A), and the control line 139 extends along a second longitudinal axis (i.e., along the drawing's x-axis, in other words, the second longitudinal axis runs horizontally from the left to the right in the paper plane of FIG. 2A) which intersects the first longitudinal axis. The relative orientation of the first longitudinal axis and the second longitudinal axis in one embodiment is orthogonal, although any intersecting orientation may be employed in alternative embodiments.

Along the intersection of, and formed between the word line 138 and the control line 139, the third dielectric layer 133 is deposited. The third dielectric layer 133 is composed of a material and thickness so as to provide sufficient coupling between the word line 138 and the control line 139 in proximity to the tunnel layer 136 in areas 135, the coupling, e.g., capacitive coupling, between the word line 138 and the control line 139 reducing the barrier height of the second dielectric layer 136 in areas 135 to provide an effectively smaller thickness for charge moving, e.g., tunneling, from the word line 138 to the floating gate 134 in areas 135. In an exemplary embodiment of the invention, the third dielectric layer 133 is formed from Al₂O₃ at a thickness of 10 nm. Other materials may be alternatively used, for example, Si₃N₄, SiO₂ provided for example via an in-situ steam generated (ISSG) oxide process; as well as other thicknesses employed, e.g., in the range of about 5 nm to about 20 nm. Those skilled in the art will appreciate that a combination of different materials (having different dielectric constants) and/or thicknesses of those materials may be used in other embodiments as well.

Those skilled in the art will appreciate that other techniques can be used to emphasize the coupling effects between the word line 138 and the control line 139 in the proximity of the second dielectric layer 136 to affect the band conductance energy thereof, thereby affecting the effective thickness of the second dielectric layer 136 for charge moving, e.g., by electron tunneling, from the word line 138 to the floating gate region 134. For example, the third dielectric layer 133 may be made up of different materials of different dielectric constants and/or thicknesses. In such an instance, the portion of the gate dielectric proximate to the second dielectric layer 136 may be composed of materials which are thinner and/or which have higher dielectric constants, whereas the portion of the third dielectric layer 133 in other areas are formed from a dielectric material which is thicker and/or of a lower dielectric constant. Alternatively, the control line 139 may be formed only in the lateral areas proximate to tunnel dielectric, and not around a substantial portion of the cross-sectional surface area of the gate stack region 130 as shown in FIG. 2a. In such an embodiment, the third dielectric layer 133 may be correspondingly formed in these areas to provide the capacitive coupling between the word line 138 and the control line 139.

FIGS. 2B and 2C illustrate a reduction in the effective thickness of the tunnel dielectric as a function of a differential voltage applied between the word line 138 and the control line 139 in accordance with one embodiment of the present invention. FIG. 2B shows a clockwise rotated view of portions of the gate stack region 130, in which the vertical dimension of the gate stack region 130 extends left to right. The floating gate region 134 is oriented left-most, and the word line 138 is positioned right-most, with the tunnel dielectric located therebetween. The scale along the x-axis indicates the vertical dimension of the gate stack region 130. Further illustrated in FIG. 2B are the fringing fields occurring within areas 135 as a voltage difference is applied between the word line 138 and the control line 139.

FIG. 2C illustrates the reduction in effective tunnel thickness of the second dielectric layer 136 which results from a differential voltage applied between the word line 138 and the control line 139. The x-axis of FIG. 2C shows the vertical dimension of the second dielectric layer 136, and the y-axis (the y-axis runs perpendicular to the x-axis in the paper plane of FIG. 2C) shows the corresponding barrier height profile (eV) in areas 135 of the second dielectric layer 136. Response 252 shows the barrier height of areas 135 within the second dielectric layer 136 when the applied voltage difference 140 V1 is 0 volts, and response 254 shows the barrier height when an applied voltage difference of +4 volts (i.e., the word line 138 is +4V relative to the control line 139) is applied. As can be seen, the effective thickness of areas 135 within the second dielectric layer 136 is approximately 13 nm with 0V applied, and the effective thickness is approximately 3 nm when the applied voltage difference is +4V. The effects are also present through the application of different voltage magnitudes, specific examples, being +0.5V, +1V, +2V, +3V, +4V, +5V, +6V, +7V, and +8V. Other voltages may, of course, be used in alternative embodiments. A reduction in the effective tunnel thickness of the second dielectric layer 136 may be by 20 percent or more, for example, 25%, 35%, 40%, 45%, 50%, 65%, 75%, 80%, 90% or 95%.

As noted above, the reduction in the effective thickness of the second dielectric layer 136 enables several effects. One effect is the reduction in programming voltage needed for the memory cell 100, 200, and correspondingly, a reduction in cell programming time, as well as extended memory cell life time. For example, a conventional programming voltage of about 20V can be reduced to the range of about 6V to 10V. Furthermore, it would be possible to form a thicker than conventional second dielectric layer 136 in order to further extend the memory cells 100 lifetime, as the effective tunnel thickness could be reduced to the desired level through the application of a particular voltage difference between the word line 138 and the control line 139. The memory cell 100, 200 also exhibits improved floating gate-to-floating gate isolation due to the shielding effect provided by the overlaying control line 139. These and other effects of embodiments of the invention will be apparent to the skilled practitioner.

In a similar manner, the applied voltage can be reversed in polarity to provide an effective tunnel thickness which is greater than the physical thickness of the second dielectric layer 136, thereby inhibiting the transfer of charge from the word line 138 to the charge storage region 136. Such an embodiment could be used to deactivate unselected memory cells. This approach could also be used for memory cells constructed to have very thin second dielectric layers which are nominally operable at very low programming voltages. In such an embodiment, an inhibiting differential voltage can be used to deactivate the unselected cells. The aforementioned voltages could be employed in such and embodiment, for example, −0.5V, −1V, −2V, −3V, −4V, −5V, −6V, −7V, −8V. Other voltages may, or course, be used in alternative embodiments.

Memory Cell Arrangement Architecture

The integrated circuit having memory cell 100, 200 of embodiments of the present invention can be implemented having memory cell arrangements, e.g., memory cell arrays, of several different configurations, examples of which are further described below. In each of these embodiments, the memory cell arrangement includes a first memory cell string and a second memory cell string, each memory cell string having a plurality of serially-coupled, e.g., source-to-drain-coupled, memory cells 100, 200, each memory cell 100, 200 of the memory cells being, e.g., configured as described above. The memory cell arrangement further includes a first control line coupled to the control lines 139 of at least one of the memory cells 100, 200 within the first memory cell string, and a first word line which is coupled to the word line 138 of at least one of the tunnel transistor memory cells 100, 200 within the first memory cell string.

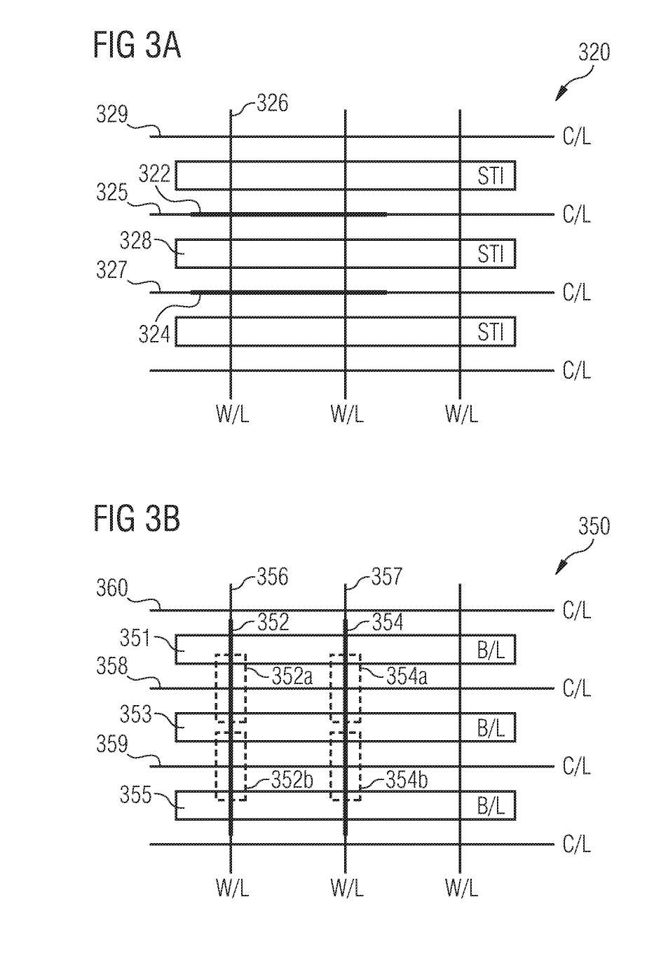

FIG. 3A illustrates a top view of a memory cell arrangement portion, e.g., of a memory array portion 320 employing memory cells in accordance with embodiments of the present invention, the memory cell array 320 being in the NAND array configuration in which the serially-coupled memory cells are formed at an intersection (usually the axis along which the serially-coupled memory cells are arranged is approximately orthogonal to the axis along which the word lines are arranged) with word lines 326 of the array.

The memory cell array 320 includes a first memory cell string 322 and a second memory cell string 324 which extend along the x-axis of the drawing, each of the first memory cell string 322 and the second memory cell string 324 being intersected by a first word line 326 which is coupled to one memory cell within each of the memory cell strings 322 and 324. In addition, a first control line 325 is coupled to each memory cell within the first memory cell string 322, and a second control line 327 is coupled to each memory cell within the second memory cell string 324. In the exemplary layout shown, the first memory cell string 322 and the second memory cell string 324 and the first control line 325 and the second control line 327 are provided in a substantially parallel orientation. Each memory cell string 322 and 324 may include a number of serially-coupled, e.g., serially source-to drain-coupled, memory cells, examples being 8, 16, or 32 cells per memory cell string 322, 324. Each memory cell string 322, 324 is coupled at each end to a bit line, which in a particular embodiment is formed below the control lines 325, 327. In a particular embodiment, select gates are additionally implemented between the memory cell strings 322, 324 and the bit line interconnect to control activation of the memory cell strings 322, 324.

Further included in the NAND memory cell array configuration is a shallow trench isolation (STI) 328 disposed between the first memory cell string 322 and the second memory cell string 324. As known in the art, the STI 328 provides isolation between the adjacent bit lines/memory cell strings 322, 324. In an exemplary embodiment, the STI barrier is a SiO₂ filled trench, laterally-offset from each memory cell string one feature size F away. STI 328 of other materials or dimensions could be employed in alternative embodiments. A cell layout size to 4F² is possible in the NAND memory cell array configuration using the memory cell of the embodiments of the present invention.

Individual memory cells in the NAND memory cell array configuration are programmed by supplying bit line voltages to the beginning and the end of its memory cell string 322, 324, in a particular embodiment 0V while supplying the desired memory cell's word line 326 with the appropriate voltage. Additionally, a control line voltage is provided to the desired memory cell along the corresponding control line 325, 327, the magnitude of the control line voltage relative to the word line voltage providing a voltage difference which operates to reduce the effective tunnel layer thickness of the memory cell. In this manner, a lower voltage (e.g., 6V to 10V) can be used to program the memory cell. Further as noted above, a differential voltage of reverse polarity can be applied to other control lines (e.g., a pass polarity applied to control line 325 and an inhibit polarity applied to control lines 327 and 329) to further inhibit unwanted programming or activation of memory cells therealong.

FIG. 3B illustrates a top view of a memory cell array portion 350 employing memory cells in accordance with an embodiment of the present invention, the memory cell array 320 being in the known virtual ground array configuration in which the memory cells which are connected in parallel are formed substantially aligned with word lines of the memory cell array.

The memory cell array includes a first memory cell string 352 and a second memory cell string 354 which extend longitudinally along the y-axis of the drawing, each memory cell coupled between two adjacent bit lines. In particular, a first bit line 351, a second bit line 353, and a third bit line 355 extend along respective first longitudinal axis, second longitudinal axis and third longitudinal axis substantially parallel to a first word line 356. The first memory cell string 352 includes a first memory cell 352a having a first source/drain region coupled to the first bit line 351, a second source/drain region coupled to the second bit line 353, and an active region and a gate stack region disposed therebetween. A second memory cell 352b in the first memory cell string 352 includes a first source/drain region coupled to the second bit line 353, a second source/drain region coupled to the third bit line 355, and an active region and a gate stack region disposed therebetween. The second memory cell string 354 similarly includes a first memory cell 354a having a first source/drain region and a second source/drain region coupled to the first bit line 351 and the second bit line 353, and a second memory cell 354b having a first source/drain region and a second source/drain region coupled to the second bit line 353 and the third bit line 355.

In this embodiment, the first word line 356 is coupled to each memory cell (i.e., the word line 138) within the first memory cell string 352. In a similar manner, the second word line 357 is coupled to each memory cell within the second memory cell string 354. A first control line 358 is coupled (via the control line 139) to one memory cell within each of the first memory cell string 352 and the second memory cell string 354. Similarly, a second control line 359 is coupled to a different one of the memory cells within each of the first memory cell string 352 and the second memory cell string 354.

Individual memory cells in the virtual ground array configuration are programmed by supplying voltage to adjacent bit lines on each side of the selected memory cell, while supplying the memory cell's word line with the desired voltage. Additionally, a control line voltage is provided to the desired memory cell along the corresponding control line, the magnitude of the control line voltage relative to the word line voltage providing a voltage difference which is operable to reduce the effective tunnel layer thickness of the memory cell. In this manner, a lower voltage may be used to program the desired memory cell. Further, the lower programming voltage may reduce or eliminate the need to bias adjacent memory cells in an off-state, as the reduced programming voltage needed in an embodiment of the present invention may be below that level which would bias adjacent memory cells in a partially on-state. Further as noted above, a differential voltage of reverse polarity can be applied to other control lines (e.g., a pass polarity applied to control line 358 and a stop polarity applied to control lines 359 and 360) to further inhibit un-wanted programming or activation of memory cells therealong.

In the particular embodiment shown, a shallow trench isolation is not provided between adjacent memory cells strings 352 and 354, as sufficient string-to-string isolation is achieved by either the reduced programming voltage required under an embodiment of the present invention, or by further biasing the adjacent memory cells to a deactivated state.

As noted above, each memory cell string 352 and 354 may include a number of serially-coupled memory cells, examples being 8, 16, or 32 cells per memory cell string. In a particular embodiment, select gates are additionally implemented between the memory cell string and the bit line interconnect to control activation of the memory cell string.

Methods of Manufacture

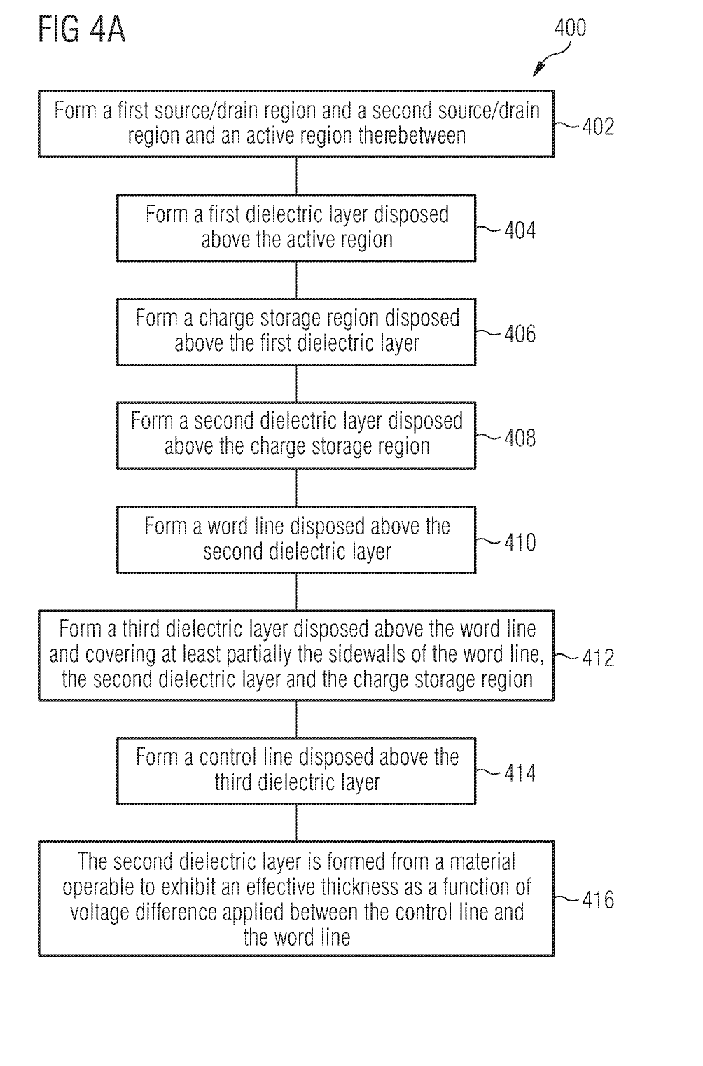

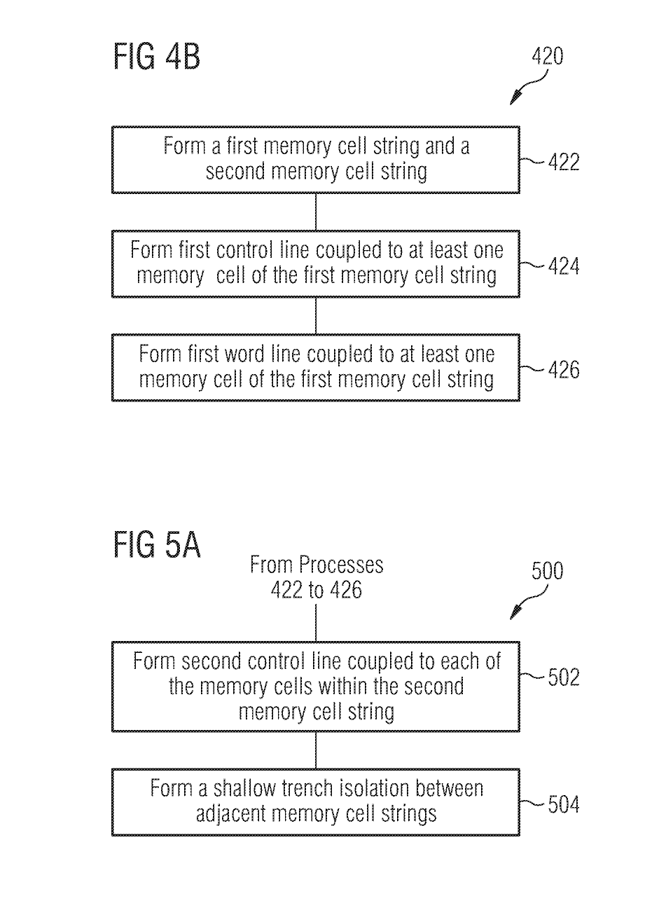

FIG. 4A illustrates an exemplary method 400 for manufacturing an integrated circuit having a memory cell 100, 200 in accordance with an embodiment of the present invention.

At 402, a first source/drain region 110 and a second source/drain region 120 are formed. This operation may be accomplished through an implantation and annealing processes carried out on the source/drain regions to be formed in the substrate. An active region is formed between the first source/drain region 110 and the second source/drain region 120.

It should be mentioned that process 402 can be carried out before the formation of a gate stack region 130 which will be described in more detail below. However, in an alternative embodiment of the invention, it is provided that the gate stack region 130 is formed first and the patterned gate stack region 130 will then be used as an implantation mask for a self-aligned formation of the first source/drain region 110 and the second source/drain region 120. In other words, in this embodiment of the invention, the process for forming the gate stack region 130 is carried out before the process 402 for forming the first source/drain region 110 and the second source/drain region 120.

As mentioned above, in an embodiment of the invention, a gate stack region 130 is formed between the first source/drain terminal 110 and the second source/drain terminal 120 on or above the active region.

A particular embodiment of this process includes forming a first dielectric layer 132 on or above at least a portion of the active region disposed on or within the substrate (operation 404). In a particular embodiment of this process, an oxide layer is thermally grown between about 2 nm to about 10 nm above the surface of the substrate.

At 406, a charge storage region 134 is formed on or above at least a portion of the first dielectric layer 132, the charge storage region 134 being, for example, a floating gate layer (poly-Si, Ti, or other electrically conductive material) or a charge trapping layer structure as described above (made of Si₃N₄, e.g.).

At 408, a second dielectric layer 136 is formed on or above at least a portion of the charge storage region 134. In an embodiment of the invention, the second dielectric layer 136 is formed to have a predefined thickness.

At 410, a word line 138 is formed on or above at least a portion of the second dielectric layer 136, the word line 138 being formed so as to receive a first voltage. Particular embodiments of the word line 138 include poly-Si, Ti or other conductive materials available in the fabrication process used.

At 412, a third dielectric layer 133 is formed on or above at least a portion of the word line 138. The third dielectric layer 133 may be an oxide such as TiO₂, SiO₂, Al₂O₃, SiN, TEOS, a nitride, or other dielectric materials available in the fabrication process implemented. The third dielectric layer 133 is formed such as to cover at least partially the sidewalls of the word line 138, the second dielectric layer 136 and the charge storage region 134 on at least one side of the word line 138, the second dielectric layer 136 and the charge storage region 134, e.g., on one side or on both sides of the word line 138, the second dielectric layer 136 and the charge storage region 134, e.g., on one exposed side or on both exposed sides of the word line 138, the second dielectric layer 136 and the charge storage region 134. In an embodiment of the material of the third dielectric layer 133 exhibits a high band gap of more than 5 eV, a high conduction band offset and valence band offset. For instance this could be Al₂O₃, SiO₂, AlN, Hf silicates with high SiO content.

At 414, a control line 139 is formed on or above at least a portion of the third dielectric layer 133, the control line 139 being formed so as to receive a second voltage. Particular embodiments of the control line 139 include poly-Si, Ti or other conductive materials available in the fabrication process employed.

The second dielectric/tunnel layer 136 is formed from an insulating material which is operable to exhibit an effective tunnel thickness as a function of the difference between the first and second voltages (block 416 in FIG. 4A). Such materials include interpoly dielectric, oxides, such as SiO₂, TiO₂, and TEOS, and nitrides, such as SiN, TiN. In a specific embodiment, the tunnel layer 136 is formed from an interpoly dielectric, and more particularly, a material which is substantially “trapless,” such as, e.g., silicon oxide (SiO₂), trapless nitride, hafnium silicate, aluminum oxide (Al₂O₃), aluminates (e.g., AlHfOₓ), or double-layer or triple-layer stacks like SiO₂/Si₃N₄/SiO₂. As noted above, the effective thickness of the tunnel layer 134 is reduced below its predefined thickness when the voltage applied to the word line 138 is high relative to the voltage applied to control line 139. When the polarity of the control line voltage and the word line voltage are reversed and the word line voltage is lower than that applied to the control line 139, the effective thickness of the second dielectric layer 136 is increased above its predefined thickness.

FIG. 4B illustrates an exemplary method 420 for manufacturing an integrated circuit having a memory cell arrangement in accordance with the present invention. At 422, at least a first memory cell string and a second memory cell string are formed, each memory cell string comprising a plurality of (e.g., source-to-drain) memory cells which are connected in parallel. In a particular embodiment of the invention, each of the memory cells is formed according to the processes 402 to 416, illustrated in FIG. 4A.

At 424, a first control line is formed coupled to the control line of at least one of the memory cells within the first memory cell string. In one embodiment of the invention, in which a NAND memory cell array configuration is implemented, the first control line is coupled to each of memory cells within the first memory cell string, as the first memory cell string and the first control line run substantially parallel with each other. In another embodiment of the invention, in which a virtual ground memory cell array configuration is employed, the first control line is coupled to only one of the memory cells in the first cell string, as the first memory cell string runs substantially perpendicular to the first control line. Each of these embodiments is further described and illustrated below.

At 426, a first word line is formed coupled to at least one of the memory cells within the first memory cell string. In one embodiment of the invention in which a NAND memory cell array configuration is implemented, the first word line is coupled to only one of the serially-coupled memory cells within the first memory cell string, as the first memory cell string and the first word line run substantially perpendicular to each other. In another embodiment of the invention in which a virtual ground array configuration is employed, the first word line is coupled to each of the memory cells in the first memory cell string, as the first memory cell string of serially-coupled memory cells and the first word line run substantially parallel to each other. Each of these embodiments is further described and illustrated below.

NAND Memory Cell Configuration

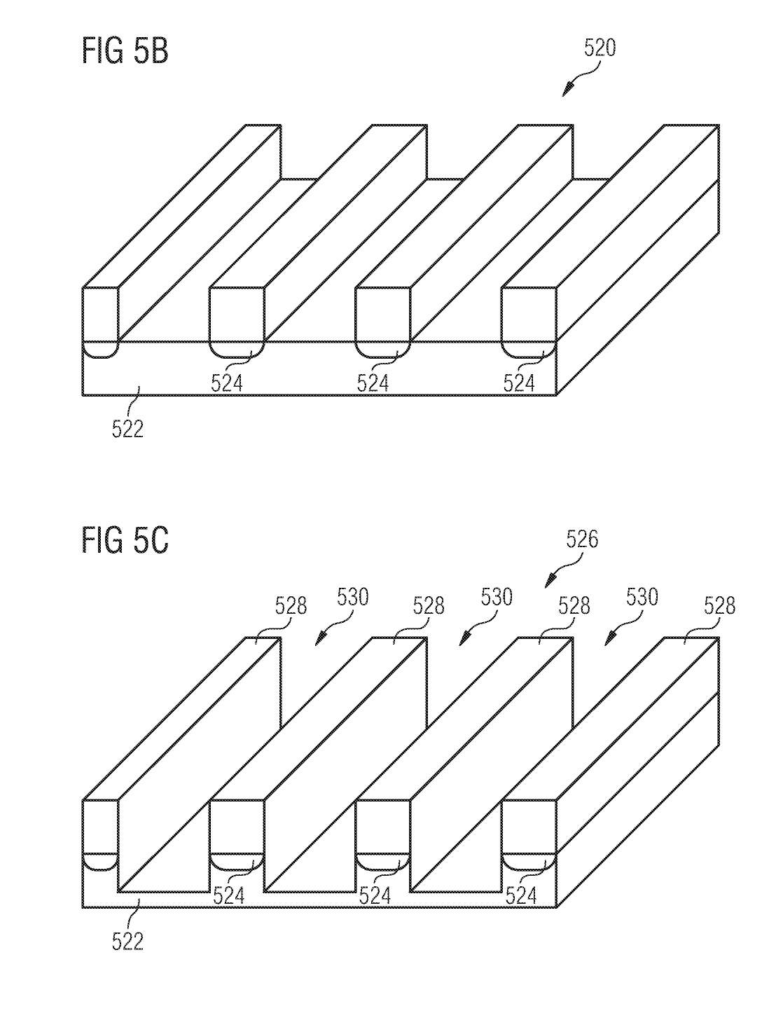

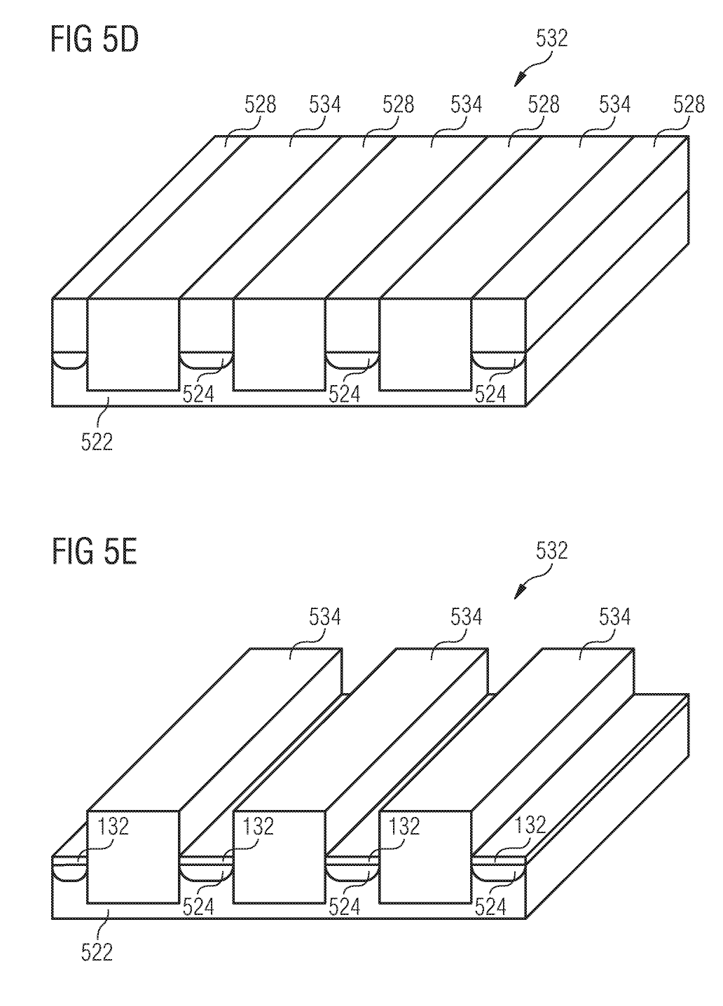

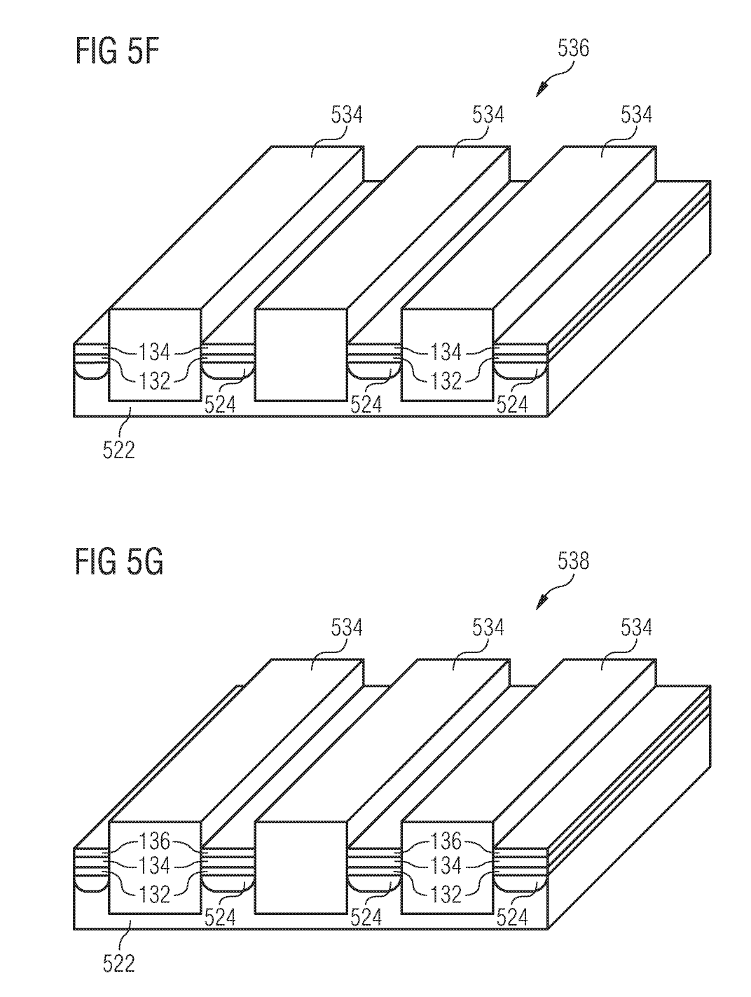

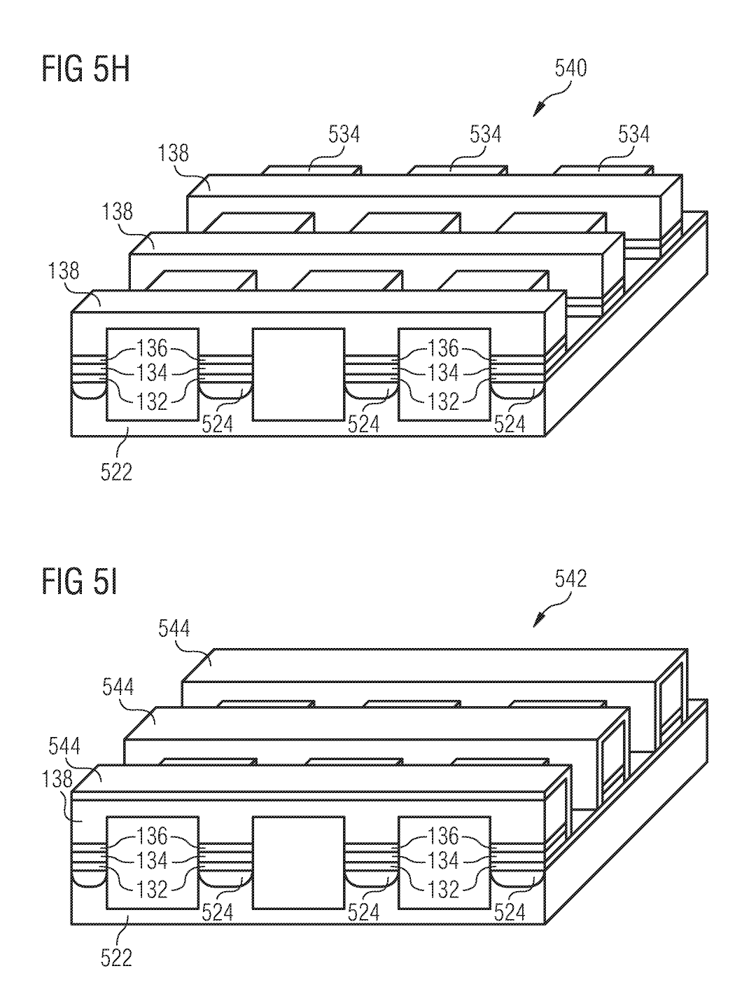

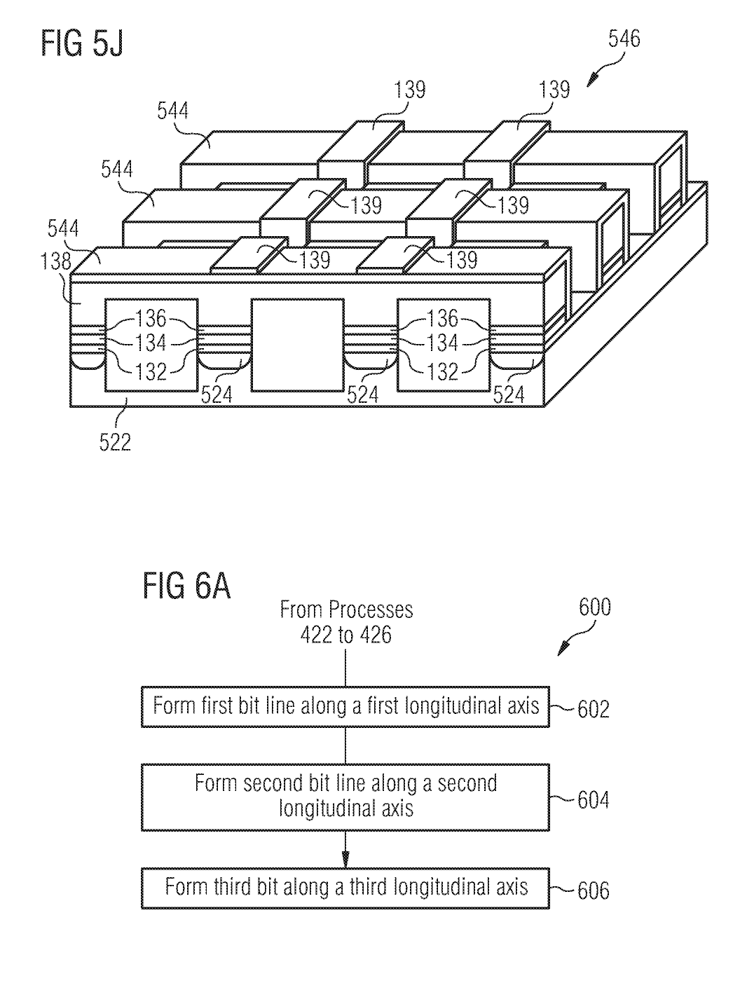

FIG. 5A illustrates specific processes 500 for manufacturing an integrated circuit having a memory cell arrangement, e.g., a memory cell array, in a NAND configuration in accordance with an embodiment of the present invention.

The method 500 begins as a continuation of the processes 422 to 426. Specifically, the method 500 includes the process of 422, in which at least a first memory cell string and a second memory cell string (e.g., 322 and 324) are formed, each memory cell string being composed of a plurality of serially-coupled memory cells as described above. The method additionally includes an embodiment of process 424, in which the first control line (e.g., 325) is coupled to each of the memory cells within the first memory cell string. The method 500 further includes an embodiment of process 426, in which the first word line (e.g., 326) is coupled to only one of the memory cells within the first memory cell string. In this embodiment, the first memory cell string and the second memory cell string are formed to be aligned longitudinally along a respective first longitudinal axis and a second longitudinal axis, whereby the first word line intersects the first memory cell string and the second memory cell string.

The method continues at 502, where a second control line (e.g., 327) is formed, the second control line being coupled to each of the memory cells in the second memory cell string. As described and shown above, a control line will extend substantially in parallel with the memory cell strings in the NAND memory cell array configuration, and accordingly that control line will couple to each memory cell within the respective memory cell string.

At 504, a shallow trench isolation (STI) (e.g., 328) is formed between the adjacent (e.g., the first memory cell string and the second memory cell string) memory cell strings. The STI provides improved isolation between adjacent memory cell strings. It is noted that the aforementioned processes may be carried out in any particular order, for example, the formation of the STI structures may precede that of the word line formation or control line formation, as illustrated below.

FIGS. 5B to 5E illustrate perspective views of a memory cell array in a NAND configuration at various stages of processing in accordance with an embodiment of the present invention.

The memory cell structure illustrated is a Flash floating gate memory cell, but as noted above, memory cells of different technologies and/or architectures may be used instead.

Initially, wells 524 (e.g., p-wells) are implanted within a bulk substrate 522 (see structure 520 in FIG. 5B).

Then, STI trenches 530 are formed, e.g., etched and filled (e.g., using SiO₂), thereby forming STI structures 534 (see structure 532 in FIG. 5D). The STI trenches 530 are arranged between two respective memory cell strings to be formed. When forming the STI trenches 530, a hardmask 528 enabling a high aspect ratio is used (see structure 526 in FIG. 5C). The hardmask 528 used may be a nitride, an oxide, such as SiO₂, TEOS, ISSG oxide, or another isolation material available in the particular process employed. Furthermore, carbon may be used as the hardmask 528. In an alternative embodiment of the invention, also a photoresist may be used instead or in addition to the usage of the hardmask 528.

After having removed the hardmask 528, a first dielectric layer 132 is next deposited (e.g., grown thermal oxide, e.g., silicon oxide) between the STI structures 534, which act as an alignment means for aligning the floating gate and the control line to be formed. Next, a floating gate layer 134, e.g., made of polysilicon (doped or undoped) or any other suitable electrically conductive material is deposited on the first dielectric layer 132. A chemical mechanical polishing (CMP) process is carried out planarizing the floating gate layer 134. Furthermore, the recess process is performed on the floating gate layer 134, thereby recessing the floating gate layer 134 with respect to the STI structures 534. The resulting structure 536 is shown in FIG. 5F. In an alternative embodiment of the invention, the floating gate serves as a mask for the STI trenches as described above.

Then, a second dielectric layer 136, e.g. made of a grown silicon oxide, is grown on the floating gate layer 134. The resulting structure 538 is shown in FIG. 5G. In an alternative embodiment of the invention, the second dielectric layer 136 may be made, e.g., of a nitride layer, e.g., a silicon nitride layer, e.g., a substantially trapless nitride layer, being deposited on the floating gate layer 134, wherein the deposited nitride layer would also be deposited on the sidewall surfaces of the STI structures 534 (not shown).

Next, poly-silicon is deposited. Using lithographic processes and a self-aligned etch of the deposited poly-silicon, the second dielectric layer 136 and the floating gate layer 134, the word lines 138 are formed. The resulting structure 540 is shown in FIG. 5H.

Then, the first source/drain region 110 and the second source/drain region 120 are formed by implantation using the word line 138 as an implantation mask. Thus, the implantation of the first source/drain region 110 and the second source/drain region 120 is carried out in a self-aligned manner.

Then, a word line isolation structure 544 is formed by depositing TEOS or silicon oxide, for example. In an alternative embodiment of the invention, in-situ steam generated (ISSG) oxide may be used for the word line isolation structure 544, providing the effect of growing a sidewall oxide at the tunnel dielectric (if nitride is used) and at the poly-Si floating gate with similar thickness. In yet another alternative embodiment of the invention, any other suitable insulating material may be used for the word line isolation structure 544. The resulting structure 542 is shown in FIG. 5I for the case of an ISSG isolation oxide.

In a following process, a layer of poly-silicon is deposited and patterned using a lithographic process and an etch process, thereby forming the control lines 139. The resulting structure 546 is shown in FIG. 5J.

Virtual Ground Array Configuration

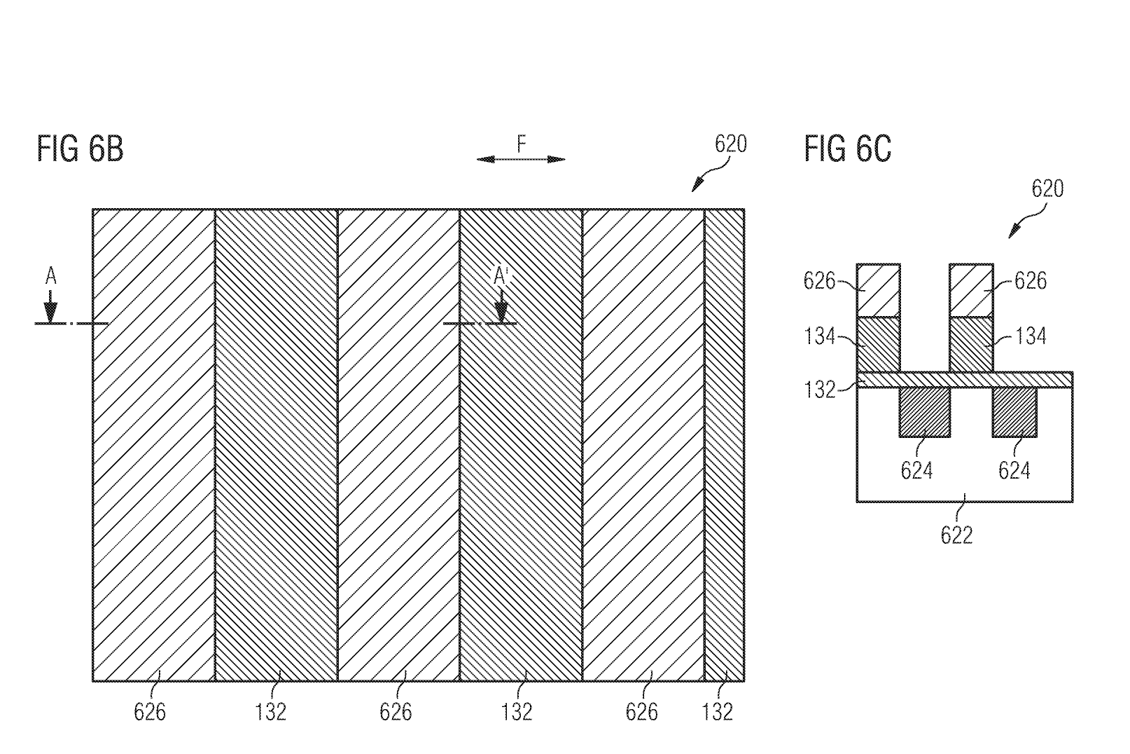

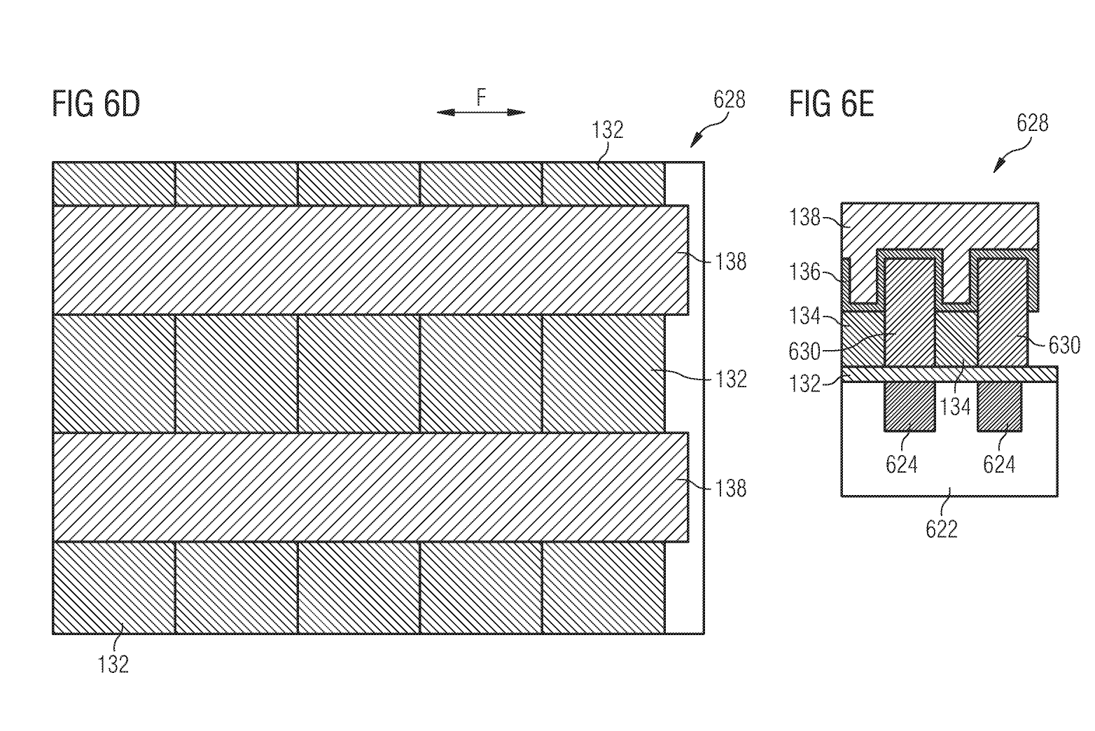

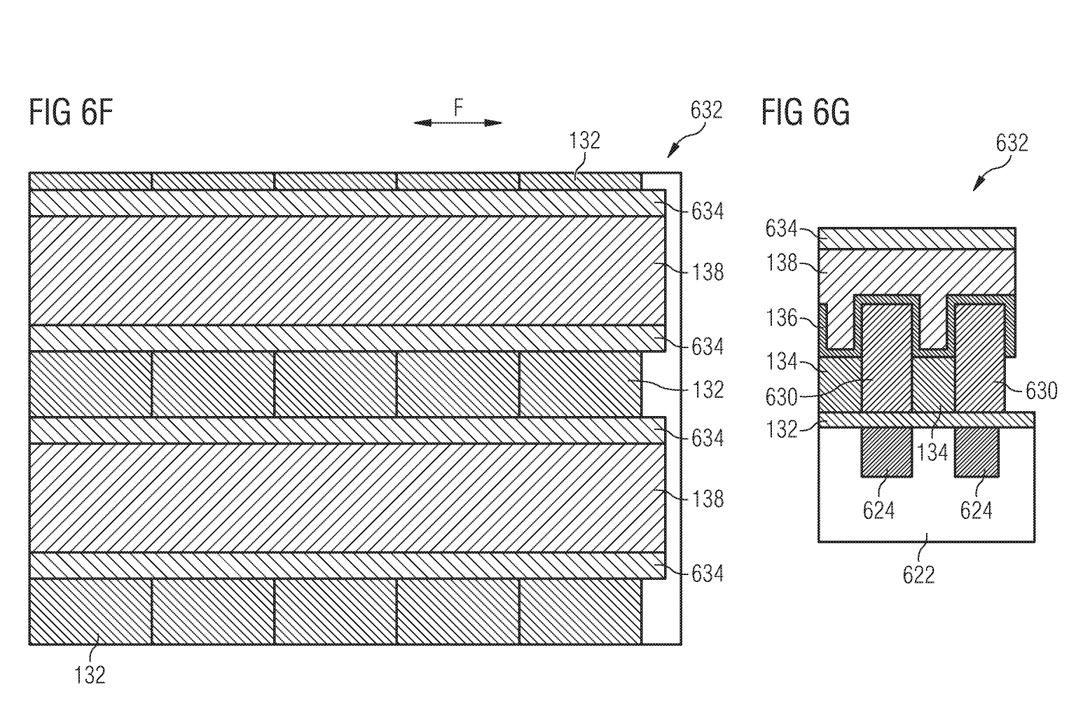

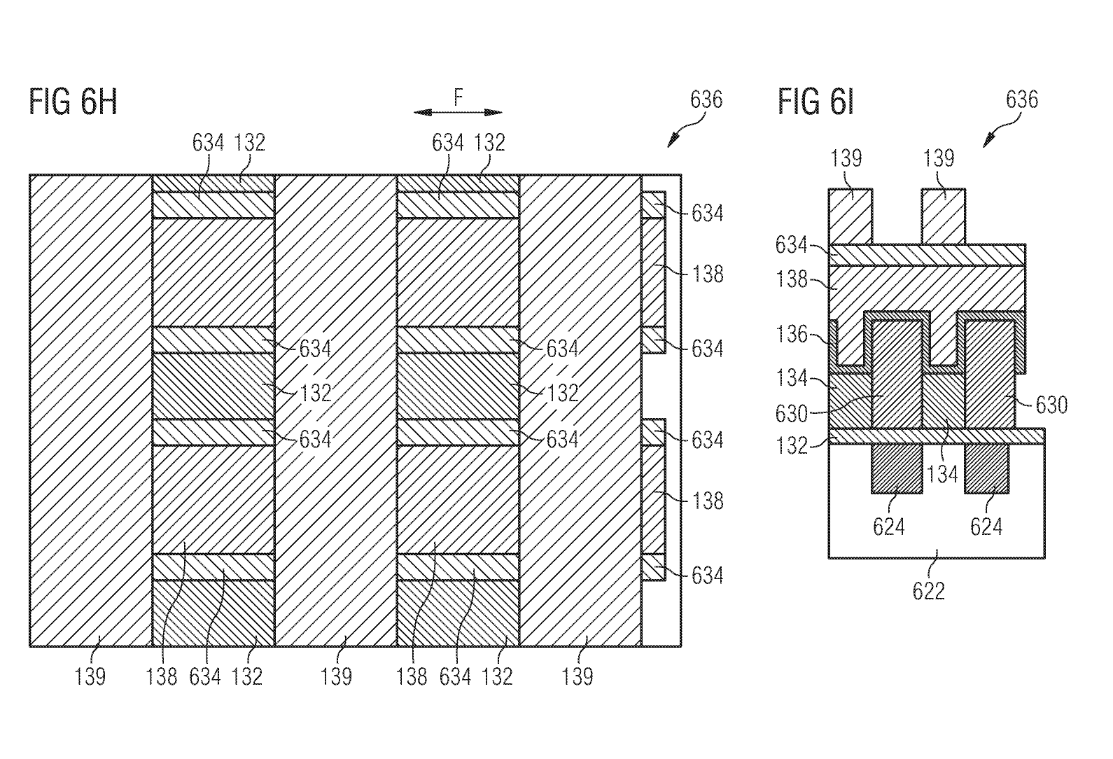

FIG. 6A illustrates specific processes 600 for manufacturing a memory cell array in a virtual ground memory cell configuration in accordance with an embodiment of the present invention.

The method 600 begins as a continuation of the processes 422 to 426. Specifically, the method 600 includes the process of 422, in which at least a first memory cell string and a second memory cell string (e.g., 352, 354) are formed, each memory cell string being composed of a plurality of coupled memory cells as described above.

The method 600 additionally includes an embodiment of process 424, in which the first control line (e.g., 358) is coupled to only one of the memory cells within the first memory cell string.

The method 600 further includes an embodiment of process 426, in which the first word line (e.g., 356) is coupled to each of the memory cells within the first memory cell string. In this embodiment, the first memory cell string and the second memory cell string are formed to be aligned longitudinally along a respective first axis and second axis, whereby the first control line intersects the first memory cell string and the second memory cell string.

The method 600 continues at 602, where a first bit line (e.g., 351) extending along a first longitudinal axis is formed.

At 604 and 606, a second bit line and a third bit line (e.g., 353, 355) are formed, respectively, each of the second bit line and the third bit line extending along a respective second longitudinal axis and third longitudinal axis each substantially being arranged parallel to the first longitudinal axis.

Further particularly, the process in 422 of forming the first memory cell string will include the operations of forming a first memory cell (e.g., 352a) having a first source/drain region coupled to the first bit line, a second drain/source region coupled to the second bit line, and forming a second memory cell (e.g., 352b) having a first source/drain region coupled to the second bit line, and a second source/drain region coupled to the third bit line.

The process in 422 of forming the second memory cell string will similarly include forming a first memory cell (e.g., 354a) having a first source/drain region coupled to the first bit line, a second source/drain region coupled to the second bit line, and forming a second memory cell (e.g., 354b) having a first source/drain region coupled to the second bit line, and a second source/drain region coupled to the third bit line. It is noted that the aforementioned processing steps may be carried out in any particular order, for example the formation of the control line may precede that of the word line. A specific embodiment of a virtual ground array manufacturing process in which memory cells are employed is illustrated below.

It is to be noted that in the virtual ground array configuration an STI barrier is not needed, as adjacent memory cell strings can be deactivated through supplying the appropriate bit line voltages thereto. In addition, an embodiment of the present invention provides for a technique whereby an inhibiting differential voltage can be supplied between the control line and word line to further turn off any unselected memory cells.

FIGS. 6B to 6I illustrate top views and cross sectional views of an integrated circuit having a memory cell array in a virtual ground configuration at various stages of processing in accordance with an embodiment of the present invention. The memory cell structure illustrated is a Flash floating gate memory cell structure, but as noted above, memory cells of different technologies and/or architectures may be used instead.

FIG. 6B illustrates a top view and FIG. 6C illustrates a cross sectional view along cross sectional line A-A′ of an integrated circuit having a memory cell array in a virtual ground configuration at a first stage of processing in accordance with an embodiment of the present invention

Initially, a bulk substrate 622 is provided. Then, wells (e.g., p-wells) are implanted within the bulk substrate 622 (see structure 620 in FIG. 6B and FIG. 6C). Next, the first dielectric layer 132 (e.g., thermally grown oxide) is deposited. Next, the charge storage region 134 (e.g., poly-Si for a floating gate structure or nitride, e.g., silicon nitride, for a charge trapping structure), and another dielectric layer 626 (e.g., a nitride layer or SiO₂ layer) are deposited over the charge storage region 134. The charge storage region 134 and the other dielectric layer 626 are masked using a lithographic process, for example, and etched, thereby defining the gate stack region 130 of the memory cells to be formed. The strips of bulk substrate 622, which are exposed from the charge storage region 134 and the other dielectric layer 626, are implanted to form diffused bit line structures 624, which will form the first source/drain region and the second source/drain region of the memory cells. The resulting structure 620 is shown in FIG. 6B and FIG. 6C.

FIG. 6D illustrates a top view and FIG. 6E illustrates a cross sectional view of a memory cell array in a virtual ground configuration at a second stage of processing in accordance with an embodiment of the present invention

Then, an isolating material 630 is deposited on the exposed regions of the first dielectric layer 132 in such a way that the space between the stacks formed by the charge storage region 134 and the other dielectric layer 626 are filled and possibly overfilled with the isolating material 628. In one embodiment of the invention, TEOS may be used as the isolating material 628, although any other suitable isolating material may be used instead. Next, a CMP is performed on the resulting structure to remove the overfilling isolating material 630, thereby forming a planar surface formed by the other dielectric layer 626 and the isolating material 630. Next, the other dielectric layer 626, e.g., the nitride, is etched selectively to the isolating material 630. Thus, the other dielectric layer 626 is entirely removed.

Next, the charge storage region 134 is partially removed, in other words, recessed, and the second dielectric layer 136 (e.g., a trapless nitride layer or a trapless SiO₂ layer) is deposited. Next, poly-silicon, in general, the material used for the word line 138 to be formed, is deposited on or above the second dielectric layer 136, and, using a lithographic process and an etch process, the word lines 138 are formed on or above the second dielectric layer 136. Using the lithographic process and the etch process, the poly-silicon and the material of the second dielectric layer 136 and the charge storage region 134 between the formed word lines 138 are removed, thereby exposing the upper surface of the first dielectric layer 132 between the formed word lines 138 (see FIG. 6D). The resulting structure 628 is shown in FIG. 6D and FIG. 6E.

FIG. 6F illustrates a top view and FIG. 6G illustrates a cross sectional view of a memory cell array in a virtual ground configuration at a third stage of processing in accordance with an embodiment of the present invention.

Next, an ISSG oxide structure 634 is formed on the structure 628 to isolate the word lines 138 and the charge storage regions 134 of memory cells of adjacent word lines 138 from one another. The resulting structure 632 is shown in FIG. 6F and FIG. 6G.

FIG. 6H illustrates a top view and FIG. 6I illustrates a cross sectional view of a memory cell array in a virtual ground configuration at a fourth stage of processing in accordance with an embodiment of the present invention.

In a further process, a conductive material such as, e.g., poly-silicon, in general, the material that will form the control line 139, is deposited on the structure 632. Next, using a lithographic process and an etch process (etching down to the upper surface of the ISSG oxide structure 634), the control lines 139 are formed on or above the ISSG oxide structure 634, in general, the third dielectric layer. The resulting structure 636 is shown in FIG. 6H and FIG. 6I.

As readily appreciated by those skilled in the art, the described processes may be implemented in hardware, software, firmware or a combination of these implementations as appropriate. In addition, some or all of the described processes may be implemented as computer readable instruction code resident on a computer readable medium (removable disk, volatile or non-volatile memory, embedded processors, etc.), the instruction code operable to program a computer of other such programmable device to carry out the intended functions.

An embodiment of the invention provides an integrated circuit having a memory cell operable with lower programming voltage while retaining conventional dielectric layer thicknesses in the gate stack of the memory cell. Additionally, the memory cell provides improved cell-to-cell isolation through the implementation of a control line which effectively shields the gate stack from adjacent memory cells.

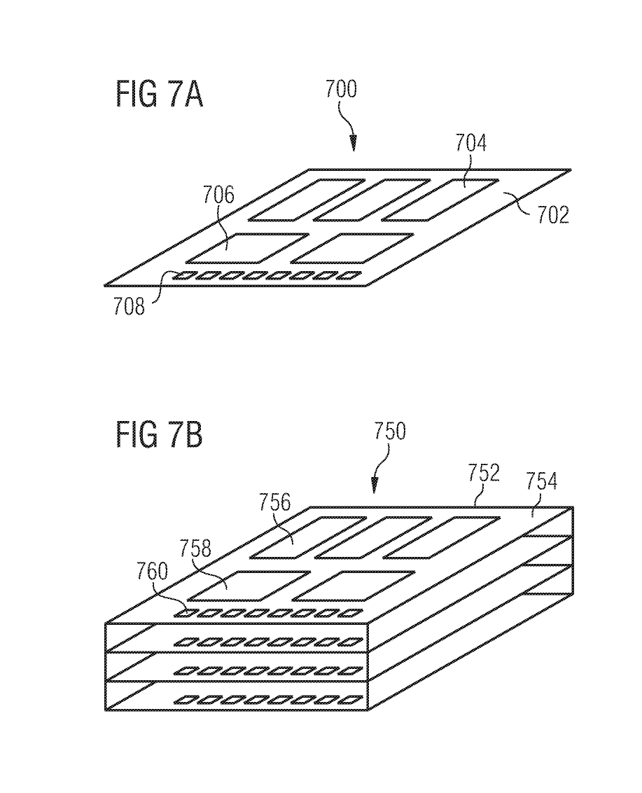

As shown in FIGS. 7A and 7B, in some embodiments, memory devices such as those described herein may be used in modules. In FIG. 7A, a memory module 700 is shown, on which one or more memory devices 704 are arranged on a substrate 702. The memory device 704 may include numerous memory cells, each of which uses a memory element in accordance with an embodiment of the invention. The memory module 700 may also include one or more electronic devices 706, which may include one or more memories, one or more processing circuitries, one or more control circuitries, one or more addressing circuitries, one or more bus interconnection circuitries, or one or more other circuitries or electronic devices that may be combined on a module with a memory device, such as the memory device 704. Additionally, the memory module 700 includes multiple electrical connections 708, which may be used to connect the memory module 700 to other electronic components, including other modules.

As shown in FIG. 7B, in some embodiments, these modules may be stackable, to form a stack 750. For example, a stackable memory module 752 may contain one or more memory devices 756, arranged on a stackable substrate 754. The memory device 756 contains memory cells that employ memory elements in accordance with an embodiment of the invention. The stackable memory module 752 may also include one or more electronic devices 758, which may include one or more memories, one or more processing circuitries, one or more control circuitries, one or more addressing circuitries, one or more bus interconnection circuitries, or one or more other circuitries or electronic devices that may be combined on a module with a memory device, such as the memory device 756. Electrical connections 760 are used to connect the stackable memory module 752 with other modules in the stack 750, or with other electronic devices. Other modules in the stack 750 may include additional stackable memory modules, similar to the stackable memory module 752 described above, or other types of stackable modules, such as stackable processing modules, control modules, communication modules, or other modules containing electronic components.

The foregoing description has been presented for purposes of illustration and description. It is not intended to be exhaustive or to limit the embodiments of the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined solely by the claims appended hereto.

What is claimed is:

1. An integrated circuit having at least one memory cell, the memory cell comprising:
a first source/drain region;
a second source/drain region;
an active region between the first source/drain region and the second source/drain region;
a first dielectric layer disposed above the active region;
a charge storage region disposed above the first dielectric layer;
a second dielectric layer disposed above the charge storage region;
a word line disposed above the second dielectric layer; and
a control line next to at least the second dielectric layer.

2. The integrated circuit of claim 1 wherein an amount of charge that passes between the word line and the charge storage region is determined as a function of a voltage difference applied between the control line and the word line.

3. The integrated circuit of claim 1, wherein the control line is at least partially next to sidewalls of the word line, the second dielectric layer and the charge storage region.

4. The integrated circuit of claim 1, further comprising:
a third dielectric layer disposed above the word line and covering at least partially the sidewalls of the word line, the second dielectric layer and the charge storage region on at least one side of the word line, the second dielectric layer and the charge storage region;
wherein the control line is disposed above the third dielectric layer.

5. The integrated circuit of claim 2,
wherein the applied voltage difference comprises a higher voltage on the word line relative to the control line, and wherein the effective tunnel thickness of the second dielectric layer under applied bias is decreased relative to a physical thickness of the second dielectric.

6. The integrated circuit of claim 2,
wherein the applied voltage difference comprises a lower voltage on the word line relative to the control line, and wherein the effective tunnel thickness of the second dielectric layer under applied bias is increased relative to a physical thickness of the second dielectric.

7. The integrated circuit of claim 1, wherein the charge storage region comprises a floating gate region.

8. The integrated circuit of claim 1, wherein the charge storage region comprises a charge trapping region.

9. The integrated circuit of claim 1, wherein the word line extends along a first longitudinal axis and wherein the control line extends along a second longitudinal axis which intersects the first longitudinal axis.

10. An integrated circuit having a memory cell arrangement, the memory cell arrangement comprising:
a first memory cell string;
a second memory cell string;
each of the first memory cell string and the second memory cell string comprising a plurality of serially source-to-drain-coupled memory cells, each memory cell comprising:
a first source/drain region;
a second source/drain region;
an active region between the first source/drain region and the second source/drain region;
a first dielectric layer disposed above the active region;
a charge storage region disposed above the first dielectric layer;
a second dielectric layer disposed above the charge storage region, the second dielectric layer having a thickness;
a word line disposed above the second dielectric layer; and
a control line next to at least the second dielectric layer;
wherein charge that passes between the word line and the charge storage region is determined as a function of a voltage difference applied between the control line and the word line.

11. The integrated circuit of claim 10, wherein the control line is at least partially next to the sidewalls of the word line, the second dielectric layer and the charge storage region.

12. The integrated circuit of claim 10, further comprising:
a third dielectric layer disposed above the word line and covering at least partially the sidewalls of the word line, the second dielectric layer and the charge storage region on at least one side of the word line, the second dielectric layer and the charge storage region;
wherein the control line is disposed above the third dielectric layer.

13. The integrated circuit of claim 10, wherein the applied voltage difference comprises a lower voltage on the word line relative to the control line, and wherein the effective tunnel thickness of the second dielectric layer is increased relative to the thickness.

14. The integrated circuit of claim 10, wherein the applied voltage difference comprises a higher voltage on the word line relative to the control line, and wherein the effective tunnel thickness of the second dielectric layer is decreased relative to the thickness.

15. The integrated circuit of claim 10, further comprising a shallow trench isolation disposed between the first memory cell string and the second memory cell string.

16. The integrated circuit of claim 10, wherein the charge storage region comprises a floating gate region.

17. The integrated circuit of claim 10, wherein the charge storage region comprises a charge trapping region.

18. The integrated circuit of claim 10, further comprising:
a first bit line extending along a first longitudinal axis in parallel to the memory cells strings;
a second bit line extending along a second longitudinal axis substantially parallel to the first longitudinal axis; and
a third bit line extending along a third longitudinal axis substantially parallel to the first and second longitudinal axes of the first and second bit lines.

19. The integrated circuit of claim 18,
wherein a first control line is disposed between the first bit line and the second bit line, and
wherein a second control line is disposed between the second bit line and the third bit line.

20. A method for manufacturing an integrated circuit having a memory cell, the method comprising:
forming a first source/drain region and a second source/drain region with an active region therebetween;
forming a first dielectric layer over the active region;
forming a charge storage region over the first dielectric layer;
forming a second dielectric layer over the charge storage region, the second dielectric layer having a thickness;
forming a word line over the second dielectric layer; and
forming a control line next to at least the second dielectric layer;
wherein charge that passes between the word line and the charge storage region is determined as a function of a voltage difference applied between the control line and the word line.

21. The method of claim 20, wherein the control line is at least partially next to the sidewalls of the word line, the second dielectric layer and the charge storage region.

22. The method of claim 20, further comprising:
forming a third dielectric layer disposed above the word line and covering at least partially the sidewalls of the word line, the second dielectric layer and the charge storage region on at least one side of the word line, the second dielectric layer and the charge storage region; and
forming the control line disposed above the third dielectric layer.

23. A method for manufacturing a memory cell arrangement, the method comprising:
forming a first memory cell string;
forming a second memory cell string;
each of the first memory cell string and the second memory cell string comprising a plurality of serially source-to-drain-coupled memory cells, the manufacturing of each memory cell comprising:
forming a first source/drain region and a second source/drain region with an active region therebetween;
forming a first dielectric layer above the active region;
forming a charge storage region above the first dielectric layer;
forming a second dielectric layer above the charge storage region, the second dielectric layer having a thickness;
forming a word line above the second dielectric layer;
forming a control line next to at least the second dielectric layer;
wherein charge that passes between the word line and the charge storage region is determined as a function of a voltage difference applied between the control line and the word line.

24. The method of claim 23, wherein the control line is formed at least partially next to the sidewalls of the word line, the second dielectric layer and the charge storage region.

25. The method of claim 23, further comprising:
forming a third dielectric layer disposed above the word line and covering at least partially the sidewalls of the word line, the second dielectric layer and the charge storage region on at least one side of the word line, the second dielectric layer and the charge storage region;
wherein the control line is formed above the third dielectric layer.

26. The method of claim 23, further comprising forming the first memory cell string and the second memory cell string to be aligned longitudinally along a respective first axis and second axis, wherein the word line intersects the first memory cell string and the second memory cell string.

27. The method of claim 26, further comprising forming a shallow trench isolation barrier disposed between the first memory cell string and the second memory cell string.

28. The method of claim 23, wherein forming the charge storage region comprises forming a floating gate region.

29. The method of claim 23, wherein forming the charge storage region comprises forming a charge trapping region.

30. The method of claim 23, further comprising:
forming a first bit line extending along a first longitudinal axis;
forming a second bit line extending along a second longitudinal axis substantially parallel to the first longitudinal axis; and
forming a third bit line extending along a third longitudinal axis substantially parallel to the first longitudinal axis and the second longitudinal axis of the first bit line and the second bit line.

31. The method of claim 30, wherein:
forming the first memory cell string comprises forming a first memory cell having a first source/drain region coupled to the first bit line, a second drain/source region coupled to the second bit line, and a second memory cell having a first source/drain region coupled to the second bit line, and a second source/drain region coupled to the third bit line; and
forming the second memory cell string comprises forming a first memory cell having a first source/drain region coupled to the first bit line, a second source/drain region coupled to the second bit line, and a second memory cell having a first source/drain region coupled to the second bit line, and a second source/drain region coupled to the third bit line.

32. An integrated circuit having a memory cell arrangement, the memory cell arrangement comprising:
a plurality of memory cells being coupled in a virtual ground structure, each memory cell comprising:
a first source/drain region;
a second source/drain region;
an active region between the first source/drain region and the second source/drain region;
a first dielectric layer disposed above the active region;
a charge storage region disposed above the first dielectric layer;
a second dielectric layer disposed above the charge storage region, the second dielectric layer having a thickness;
a word line disposed above the second dielectric layer;
a control line next to at least the second dielectric layer;
wherein charge that passes between the word line and the charge storage region is determined as a function of a voltage difference applied between the control line and the word line.

33. The integrated circuit of claim 32, wherein the control line is at least partially next to the sidewalls of the word line, the second dielectric layer and the charge storage region.

34. The integrated circuit of claim 32, wherein each memory cell further comprises:
a third dielectric layer disposed above the word line and covering at least partially the sidewalls of the word line, the second dielectric layer and the charge storage region;
wherein the control line is disposed above the third dielectric layer.

35. The integrated circuit of claim 32, wherein the applied voltage difference comprises a lower voltage on the word line relative to the control line, and wherein an effective tunnel thickness of the second dielectric layer is increased relative to the thickness.

36. The integrated circuit of claim 32, wherein the applied voltage difference comprises a higher voltage on the word line relative to the control line, and wherein an effective tunnel thickness of the second dielectric layer is decreased relative to the thickness.

37. The integrated circuit of claim 32, further comprising buried bit lines connecting the memory cells.

38. The integrated circuit of claim 37, wherein the buried bit lines are arranged in parallel to the control lines.

39. The integrated circuit of claim 32, wherein the charge storage region comprises a floating gate region.

40. The integrated circuit of claim 32, wherein the charge storage region comprises a charge trapping region.

41. A method for manufacturing an integrated circuit having a memory cell arrangement, the method comprising:
forming a plurality of memory cells that are coupled in a virtual ground structure, the manufacturing of each memory cell comprising:
forming a first source/drain region, and a second source/drain region with an active region therebetween;
forming a first dielectric layer above the active region;
forming a charge storage region above the first dielectric layer;
forming a second dielectric layer above the charge storage region, the second dielectric layer having a thickness;
forming a word line above the second dielectric layer; and
forming a control line next to at least the second dielectric layer;
wherein the charge passes between the word line and the charge storage region is determined as a function of a voltage difference applied between the control line and the word line.

42. The method of claim 41, wherein the control line is formed at least partially next to the sidewalls of the word line, the second dielectric layer and the charge storage region.

43. The method of claim 41, the manufacturing of each memory cell further comprising:
forming a third dielectric layer disposed above the word line and covering at least partially the sidewalls of the word line, the second dielectric layer and the charge storage region on at least one side of the word line, the second dielectric layer and the charge storage region;
wherein the control line is formed above the third dielectric layer.

44. The method of claim 41, wherein forming the charge storage region comprises forming a floating gate region.

45. The method of claim 41, wherein forming the charge storage region comprises forming a charge trapping region.

46. The method of claim 41, further comprising forming buried bit lines connecting the memory cells.

47. The method of claim 46, wherein the buried bit lines are arranged in parallel to the control lines.

48. An integrated circuit having at least one charge storage memory cell, the charge storage memory cell comprising:
a dielectric layer disposed above a charge storage region, the dielectric layer having a predefined thickness;
a word line disposed above the dielectric layer;
a control line next to at least the second dielectric layer;
wherein charge that passes between the word line and the charge storage region is determined as a function of a voltage difference applied between the control line and the word line.

49. The integrated circuit of claim 48, wherein the control line is at least partially next to the sidewalls of the word line, the second dielectric layer and the charge storage region.

50. The integrated circuit of claim 48, further comprising:
another dielectric layer disposed above the word line and at least partially covering the sidewalls of the word line, the dielectric layer and the charge storage region on at least one side of the word line, the dielectric layer and the charge storage region;
wherein the control line is disposed above the other dielectric layer.

51. The integrated circuit of claim 48, wherein the applied voltage difference comprises a higher voltage on the word line relative to the control line, and wherein the effective tunnel thickness of the dielectric layer under applied bias is decreased relative to the thickness.

52. The integrated circuit of claim 48, wherein the applied voltage difference comprises a lower voltage on the word line relative to the control line, and wherein the effective tunnel thickness of the dielectric layer under applied bias is increased relative to the thickness.

53. The integrated circuit of claim 48, wherein the charge storage region comprises a floating gate region.

54. The integrated circuit of claim 48, wherein the charge storage region comprises a charge trapping region.

55. The integrated circuit of claim 48, wherein the word line extends along a first longitudinal axis and wherein the control line extends along a second longitudinal axis which intersects the first longitudinal axis.

56. A method of manufacturing an integrated circuit having at least one charge storage memory cell, the method comprising:
forming a dielectric layer above a charge storage region, the dielectric layer having a predefined thickness;
forming a word line above the dielectric layer;
forming a control line next to at least the second dielectric layer;
wherein charge that passes between the word line and the charge storage region is determined as a function of a voltage difference applied between the control line and the word line.

57. The method of claim 56, wherein the control line is formed at least partially next to the sidewalls of the word line, the second dielectric layer and the charge storage region.

58. An integrated circuit having at least one charge storage memory cell, the charge storage memory cell comprising:
a dielectric layer disposed above a charge storage region;
a word line disposed above the dielectric layer; and
a control line at least next to the dielectric layer.

59. A memory module, comprising:
a plurality of integrated circuits, wherein at least one integrated circuit of the plurality of integrated circuits comprises a memory cell arrangement, the memory cell arrangement comprising:
a dielectric layer disposed above a charge storage region, the dielectric layer having a thickness;
a word line disposed above the dielectric layer; and
a control line at least next to the dielectric layer.

60. The memory module of claim 59, wherein the memory module is a stackable memory module in which at least some of the integrated circuits are stacked one above the other.
